(19) United States
(12) Patent Application Publication
(10) Pub. No.: US 2015/0176124 A1
(43) Pub. Date: Jun. 25, 2015

(54) Methods for Rapid Generation of ALD Saturation Curves Using Segmented Spatial ALD

(71) Applicant: Intermolecular, Inc., San Jose, CA (US)

(72) Inventors: Frank Greer, Pasadena, CA (US); Khaled Ahmed, Anaheim, CA (US); Chen-An Chen, San Jose, CA (US); Wenxian Zhu, E. Palo Alto, CA (US)

(73) Assignee: Intermolecular, Inc., San Jose, CA (US)

(21) Appl. No.: 14/135,266

(22) Filed: Dec. 19, 2013

(51) Int. Cl. C23C 16/455; C23C 16/52

(52) U.S. Cl. CPC C23C 16/455; C23C 16/52

(57) ABSTRACT

Systems and methods for rapid generation of ALD saturation curves using segmented spatial ALD are disclosed. Methods include introducing a substrate, having a plurality of substrate segment regions, into a processing chamber. The substrate may be disposed upon a pedestal within the chamber. Sequentially exposing the plurality of segment regions to a precursor within the chamber at a first processing temperature. Afterwards, purging the precursor from the chamber and then sequentially exposing each plurality of segment regions to a reactant within the chamber at the first processing temperature. Afterwards, purging the reactant from the chamber. Repeat sequentially exposing the plurality of segment regions to the precursor and the reactant for a plurality of cycles. Each segment region may be sequentially exposed to the precursor for a unique processing time. The pedestal may be rotated prior to exposing each next segment region to the precursor and the reactant.

### FIELD

The present disclosure relates to precursor and reactant materials for atomic layer deposition (ALD) processes.

### BACKGROUND

Evaluating the suitability of metal precursors and reactant materials for use in ALD processes is often time consuming and resource intensive. For example, conventional material evaluations involve generating saturation curves for select ALD parameters such as precursor dose time, reactant dose time, and purge time at various deposition temperatures using full wafers.

At a minimum, four precursor dose times, four reactant dose times, and three deposition temperatures are performed during the evaluation requiring several hours of equipment time and the consumption of several grams of reactive material.

It is therefore desirable to evaluate precursors more efficiently. Additionally, it is also desirable to compare the results of various process conditions when evaluating the viability of reactive materials simultaneously. The present disclosure addresses these needs.

### SUMMARY OF THE DISCLOSURE

The following summary is included in order to provide a basic understanding of some aspects and features of the present disclosure. This summary is not an extensive overview of the disclosure and as such it is not intended to particularly identify key or critical elements of the disclosure or to delineate the scope of the disclosure. Its sole purpose is to present some concepts of the disclosure in a simplified form as a prelude to the more detailed description that is presented below.

Systems and methods for rapid generation of ALD saturation curves using segmented spatial ALD are disclosed. Methods include introducing a substrate, having a plurality of substrate segment regions, into a processing chamber. The substrate may be disposed upon a pedestal within the chamber. Sequentially exposing the plurality of segment regions to a precursor within the chamber at a first processing temperature.

Afterwards, purging the precursor from the chamber and then sequentially exposing each plurality of segment regions to a reactant within the chamber at the first processing temperature. Afterwards, purging the reactant from the chamber. Repeat sequentially exposing the plurality of segment regions to the precursor and the reactant for a plurality of cycles. Each segment region may be sequentially exposed to the precursor for a unique processing time. The pedestal may be rotated prior to exposing each next segment region to the precursor and the reactant.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale. The techniques of the present disclosure may readily be understood by considering the following detailed description in conjunction with the accompanying drawings, in which:

FIG. 1 is a schematic diagram for implementing combinatorial processing.

FIG. 2 is a schematic diagram illustrating various process sequences using combinatorial processing and evaluation.

FIG. 3 is a simplified schematic diagram illustrating an integrated high productivity combinatorial (HPC) system.

FIG. 4 shows yet another illustrative embodiment of an apparatus enabling combinatorial processing.

FIG. 5 is a schematic diagram illustrating an exemplary showerhead assembly consistent with the present disclosure.

FIG. 6 is a flowchart of a method for generating saturation curves using a segmented spatial atomic layer deposition (ALD) process.

FIG. 7 is a schematic diagram illustrating process conditions for each substrate segment region on a substrate.

FIG. 8 illustrates a saturation curve.

FIG. 9 illustrates another saturation curve.

FIG. 10 illustrates a graph displaying film growth rates for a span of process temperatures for an ALD process.

### DETAILED DESCRIPTION

A detailed description of some embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to some embodiments have not been described in detail to avoid unnecessarily obscuring the description.

Systems and methods for rapid generation of ALD saturation curves using segmented spatial ALD are disclosed. Methods include introducing a substrate, having a plurality of substrate segment regions, into a processing chamber. The substrate may be disposed upon a pedestal within the chamber. Sequentially exposing the plurality of segment regions to a precursor within the chamber at a first processing temperature.

Afterwards, purging the precursor from the chamber and then sequentially exposing each plurality of segment regions to a reactant within the chamber at the first processing temperature. Afterwards, purging the reactant from the chamber. Repeat sequentially exposing the plurality of segment regions to the precursor and the reactant for a plurality of cycles. Each segment region may be sequentially exposed to the precursor for a unique processing time. The pedestal may be rotated prior to exposing each next segment region to the precursor and the reactant.

It is to be understood that unless otherwise indicated this disclosure is not limited to specific layer compositions or surface treatments. It is also to be understood that the terminology used herein is for the purpose of describing particular embodiments only and is not intended to limit the scope of the present disclosure.

It must be noted that as used herein and in the claims, the singular forms “a,” and “the” include plural referents unless the context clearly dictates otherwise. Thus, for example, reference to “a layer” also includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the disclosure. The upper and lower limits of these smaller ranges may independently be included in the smaller ranges, and are also encompassed within the disclosure, subject to any specifically excluded limit in the stated range. Where the stated range includes one or both of the limits, ranges excluding either or both of those included limits are also included in the disclosure. The term “about” generally refers to ±10% of a stated value.

The term “segment processing” as used herein refers to providing distinct processing conditions, such as controlled temperature, flow rates, chamber pressure, processing time, plasma composition, and plasma energies. Substrate segment regions may provide complete isolation between regions or relative isolation between regions. Preferably, the relative isolation is sufficient to provide a control over processing conditions within ±10%, within ±5%, within ±2%, within ±1%, or within ±0.1% of the target conditions. Where one region is processed at a time, adjacent regions are generally protected from any exposure that would alter the substrate surface in a measurable way.

The term “substrate segment region” as used herein refers to a localized area on a substrate which is, was, or is intended to be used for processing or formation of a selected material. The region may include one region and/or a series of regular or periodic regions predefined on the substrate. The region may have any convenient shape, e.g., sector, circular, rectangular, elliptical, wedge-shaped, etc. In the semiconductor field, a region may be, for example, a test structure, single die, multiple dies, portion of a die, other defined portion of substrate, or an undefined area of a substrate, e.g., blanket substrate which is defined through the processing.

The term “substrate” as used herein may refer to any workpiece on which formation or treatment of material layers is desired. Substrates may include, without limitation, silicon, coated silicon, other semiconductor materials, glass, polymers, metal foils, sapphire, aluminum oxide, etc. The term “substrate” or “wafer” may be used interchangeably herein. Semiconductor wafer shapes and sizes may vary and include commonly used round wafers of 2″, 4″, 200 mm, or 300 mm in diameter.

It is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration,” on a single substrate without the need of consuming the equivalent number of monolithic substrates per material(s), processing condition(s), sequence(s) of processing conditions, sequence(s) of processes, and combinations thereof. This may greatly improve both the speed and reduce the costs associated with the discovery, implementation, optimization, and qualification of material(s), process(es), and process integration sequence(s) required for manufacturing.

Systems and methods for HPC™ processing are described in U.S. Pat. No. 7,544,574 filed on Feb. 10, 2006; U.S. Pat. No. 7,824,935 filed on Jul. 2, 2008; U.S. Pat. No. 7,871,928 filed on May 4, 2009; U.S. Pat. No. 7,902,063 filed on Feb. 10, 2006; and U.S. Pat. No. 7,947,531 filed on Aug. 28, 2009 which are all herein incorporated by reference for all purposes.

Systems and methods for HPC™ processing are further described in U.S. Pat. No. 8,084,400 filed on Feb. 10, 2006, claiming priority from Oct. 15, 2005; U.S. Patent Application No. 2007/0267631 filed on May 18, 2006, claiming priority from Oct. 15, 2005; U.S. Patent Application No. 2007/0202614 filed on Feb. 12, 2007, claiming priority from Oct. 15, 2005; U.S. Patent Application No. 2013/0065355 filed on Sep. 12, 2011; and U.S. Patent Application No. 2007/0202610 filed on Feb. 12, 2007, claiming priority from Oct. 15, 2005 which are all herein incorporated by reference for all purposes.

HPC™ processing techniques have been successfully adapted to wet chemical processing such as etching, texturing, polishing, cleaning, etc. HPC™ processing techniques have also been successfully adapted to deposition processes such as physical vapor deposition (PVD) (i.e. sputtering), atomic layer deposition (ALD), and chemical vapor deposition (CVD).

In addition, systems and methods for combinatorial processing are further described in U.S. Patent Application No. 2013/0168231 filed on Dec. 31, 2011 and U.S. Patent Application No. 2013/0130490 filed on Nov. 22, 2011 which are all herein incorporated by reference for all purposes.

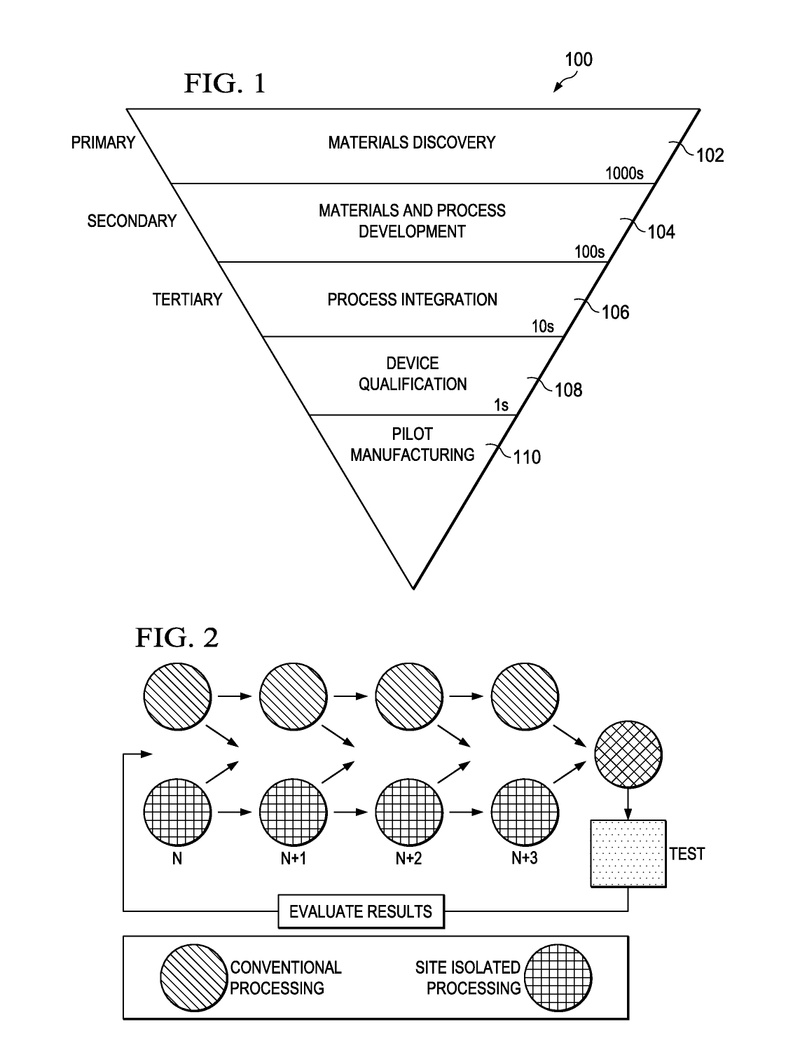

FIG. 1 illustrates a schematic diagram 100 for implementing combinatorial processing and evaluation using primary, secondary, and tertiary screening. The schematic diagram 100 illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages may be used to refine the success criteria and provide better screening results.

For example, thousands of materials are evaluated during a materials discovery stage 102. Materials discovery stage 102 is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage 104. Evaluation of the materials is performed using metrology tools such as electronic testers and imaging tools (i.e., microscopes).

The materials and process development stage 104 may evaluate hundreds of materials (i.e., a magnitude smaller than the primary stage) and may focus on the processes used to deposit or develop those materials. Promising materials and processes are again selected, and advanced to the tertiary screen or process integration stage 106 where tens of materials and/or processes and combinations are evaluated. The tertiary screen or process integration stage 106 may focus on integrating the selected processes and materials with other processes and materials.

The most promising materials and processes from the tertiary screen are advanced to device qualification 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes may proceed to pilot manufacturing 110.

The schematic diagram 100 is an example of various techniques that may be used to evaluate and select materials and processes for the development of new materials and processes. The descriptions of primary, secondary, etc. screening and the various stages 102-110 are arbitrary and the stages may overlap, occur out of sequence, be described and be performed in many other ways.

This application benefits from HPC™ techniques described in U.S. Patent Application No. 2007/0202610 filed on Feb. 12, 2007 which is hereby incorporated for reference for all purposes. Portions of this application have been reproduced below to enhance the understanding of the present disclosure.

While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete substrate segment region. Furthermore, while different materials or unit processes may be used for corresponding layers or steps in the formation of a structure in different substrate segment regions of the substrate during the combinatorial processing, the application of each layer or use of a given unit process is substantially consistent or uniform throughout the different substrate segment regions in which it is intentionally applied. Thus, the processing is uniform within a substrate segment region (inter-region uniformity) and between substrate segment regions (intra-region uniformity), as desired. It should be noted that the process may be varied between substrate segment regions, for example, where a thickness of a layer is varied or a material may be varied between the substrate segment regions, etc., as desired by the design of the experiment.

The result is a series of substrate segment regions on the substrate that contain structures or unit process sequences that have been uniformly applied within that substrate segment region and, as applicable, across different substrate segment regions. This process uniformity allows comparison of the properties within and across the different substrate segment regions such that the variations in test results are due to the varied parameter (e.g., materials, unit processes, unit process parameters, hardware details, or process sequences) and not the lack of process uniformity. In the embodiments described herein, the positions of the discrete substrate segment regions on the substrate may be defined as needed, but are preferably systematized for ease of tooling and design of experimentation. In addition, the number, variants and location of structures within each substrate segment region are designed to enable valid statistical analysis of the test results within each substrate segment region and across substrate segment regions to be performed.

FIG. 2 is a simplified schematic diagram illustrating a general methodology for combinatorial process sequence integration that includes segment processing and/or conventional processing. In some embodiments, the substrate is initially processed using conventional process N. In some exemplary embodiments, the substrate is then processed using segment process N+1. During segment processing, an HPC™ module may be used, such as the HPC module described in U.S. Pat. No. 8,084,400 filed on Feb. 10, 2006, which is incorporated herein by reference for all purposes. The substrate may then be processed using segment process N+2, and thereafter processed using conventional process N+3. Testing is performed and the results are evaluated. The testing may include physical, chemical, acoustic, magnetic, electrical, optical, etc. tests. From this evaluation, a particular process from the various segment processes (e.g., from steps N+1 and N+2) may be selected and fixed so that additional combinatorial process sequence integration may be performed using segment processing for either process N or N+3. For example, a next process sequence may include processing the substrate using segment process N, conventional processing for processes N+1, N+2, and N+3, with testing performed thereafter.

It should be appreciated that various other combinations of conventional and combinatorial processes may be included in the processing sequence with regard to FIG. 2. That is, the combinatorial process sequence integration may be applied to any desired segments and/or portions of an overall process flow. Characterization, including physical, chemical, acoustic, magnetic, electrical, optical, etc. testing, may be performed after each process operation, and/or series of process operations within the process flow as desired. The feedback provided by the testing is used to select certain materials, processes, process conditions, and process sequences and eliminate others. Furthermore, the above flows may be applied to entire monolithic substrates, or portions of monolithic substrates such as coupons.

Under combinatorial processing operations the processing conditions at different substrate segment regions may be controlled independently. Consequently, process material amounts, reactant species, processing temperatures, processing times, processing pressures, processing flow rates, processing powers, processing reactant compositions, the rates at which the reactions are quenched, deposition order of process materials, process sequence steps, hardware details, etc., may be varied from substrate segment region to substrate segment region on the substrate. Thus, for example, when exploring materials, a processing material delivered to a first and second substrate segment region may be the same or different. If the processing material delivered to the first substrate segment region is the same as the processing material delivered to the second isolated-region, this processing material may be offered to the first and second segment regions on the substrate at different concentrations. In addition, the material may be deposited under different processing parameters. Parameters which may be varied include, but are not limited to, process material amounts, reactant species, processing temperatures, processing times, processing pressures, processing flow rates, processing powers, processing reactant compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used may be varied.

As mentioned above, within a substrate segment region, the process conditions are substantially uniform. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. However, in some embodiments, the processing may result in a gradient within the substrate segment regions. It should be appreciated that a substrate segment region may be formed on another substrate segment region in some embodiments or the substrate segment regions may be isolated and, therefore, non-overlapping. When the substrate segment regions are adjacent, there may be a slight overlap wherein the materials or precise process interactions are not known, however, a portion of the substrate segment regions, normally at least 50% or more of the area, is uniform and all testing occurs within that substrate segment region. Further, the potential overlap is only allowed with material of processes that will not adversely affect the result of the tests. Both types of substrate segment regions are referred to herein as substrate segment regions or discrete substrate segment regions.

Substrates may be a conventional round 200 mm, 300 mm, or any other larger or smaller substrate/wafer size. In some embodiments, substrates may be square, rectangular, or any other shape. One skilled in the art may appreciate that the substrate may be a blanket substrate, a coupon (e.g., partial wafer), or even a patterned substrate having predefined substrate segment regions. In some other embodiments, a substrate may have substrate segment regions defined through the processing described herein.

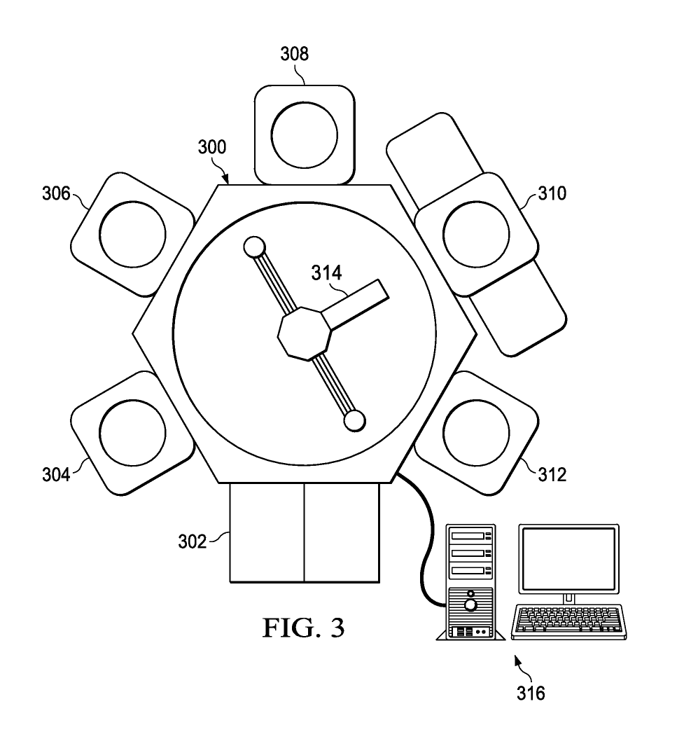

FIG. 3 is a simplified schematic diagram illustrating a HPC system. The HPC system includes a frame 300 supporting a plurality of processing modules. It will be appreciated that frame 300 may be a unitary frame in accordance with some embodiments. In some embodiments, the environment within frame 300 is controlled. A load lock 302 provides access into the plurality of modules of the HPC system. A robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that may be supported to combine combinatorial processing or combinatorial plus conventional processing of a substrate or wafer. In some embodiments, a centralized controller, i.e., computing device 316, may control the processes of the HPC system. Further details of one possible HPC system are described in U.S. Patent Application No. 2008/0017109 and U.S. Pat. No. 7,867,904, the entire disclosures of which are herein incorporated by reference for all purposes. In a HPC system, a plurality of methods may be employed to deposit material upon a substrate employing combinatorial processes.

Systems and methods for rapid generation of ALD saturation curves using segmented spatial ALD are disclosed. Methods include exposing a first plurality of substrate segment regions to a precursor at a first temperature, a second plurality of substrate segment regions at a second temperature, and a third plurality of substrate segment regions at a third temperature. The substrate segment regions within each of the plurality of substrate segment regions may be exposed to the precursor at various processing times. Next, exposing the first, second, and third plurality of substrate segment regions to a reactant thereby forming a first, second, and third plurality of composite films. The substrate segment regions within each of the plurality of substrate segment regions may be exposed to the reactant at various processing times. Further, repeating the exposing of precursor and reactant, at the respective temperatures, for a plurality of cycles.

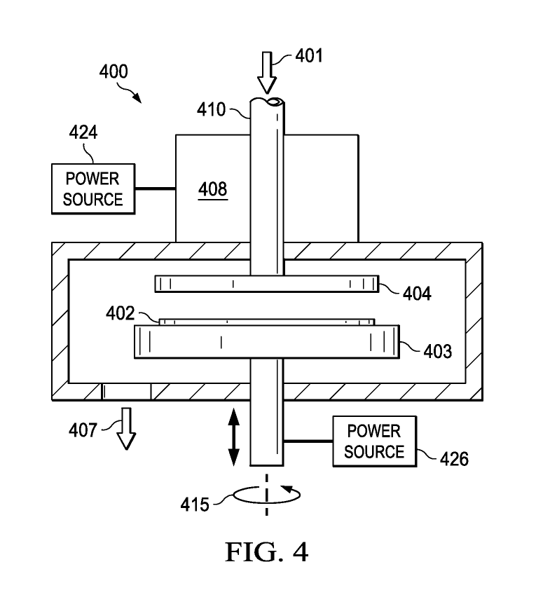

FIG. 4 shows yet another illustrative embodiment of an apparatus 400 enabling combinatorial processing. In the embodiment shown, apparatus 400 is an ALD processing tool 400 which may be used to deposit thin conformal films on a substrate 402. ALD processing tool 400 includes an inlet 410 through which precursor and reactant materials are directed therethrough (in direction 401). Showerhead 404 and substrate support assembly 403 (i.e., pedestal) may move vertically or rotate about axis 415 with a substrate 402 thereon via power supplies 424, 426.

Most notably, apparatus 400 includes spatial hardware capability that permits an operator to isolate deposition to a single substrate segment region on a substrate. For example, as many as 24 experiments can be performed on each substrate having 15 degree sector-shaped substrate segment regions. Accordingly, an entire saturation curve for ALD processes may be achieved by testing on a single substrate.

Advantageously, the amount of precursor consumed in generating a saturation curve using techniques consistent with the present disclosure is far less than prior art methods because an entire substrate (e.g., 300 mm wafer) is not required to be saturated to sufficiently evaluate a reactive material.

Furthermore, three dimensional step coverage or electrical test structures may be integrated into the substrate upon which the depositions are completed to allow physical and electrical parameters to be optimized simultaneously. Moreover, the saturation curve development may be integrated with other combinatorial processes to characterize the effect of dry or wet surface treatments on nucleation conditions.

In some embodiments, to complete the set of saturation curve experiments, the substrate temperature may be ramped up after a plurality of substrate segment regions are complete. For instance, two temperature ramp steps may be performed while generating saturation curves for 24 individual experiments using a single substrate as will be described in further detail below. The temperature ramp steps may be achieved by any of increasing the temperature of the showerhead 404, increasing the temperature of the substrate support 403, etcetera.

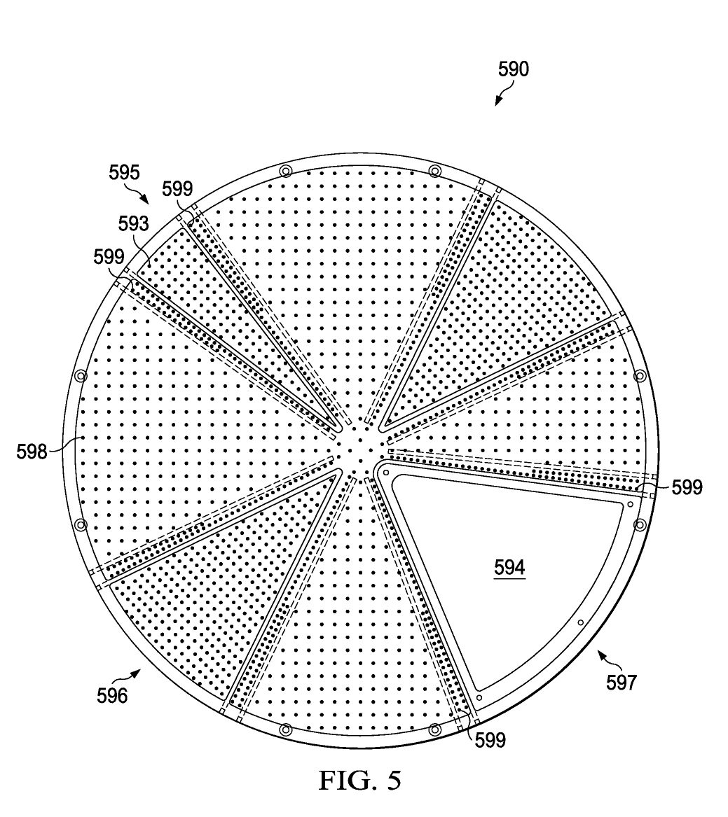

FIG. 5 is a schematic diagram illustrating an exemplary showerhead 590 assembly consistent with the present disclosure. Showerhead 590 may be formed from any known material suitable for the present disclosure, including stainless steel, aluminum, amodized aluminum, nickel, ceramics and the like.

Using a showerhead 590 as illustrated in FIG. 5 allows a substrate to be processed in a combinatorial manner wherein different parameters may be varied as discussed above. Examples of the parameters which may be varied include process material composition, process material amounts, reactive species, processing temperatures, processing times, processing pressures, processing flow rates, processing powers, processing reactant compositions, the rates at which the reactions are quenched, atmospheres in which the processes are conducted, an order in which materials are deposited, etcetera.

Notably, the showerhead 590 shown in FIG. 5 may have a plurality of gas distribution segment ports (e.g., 595, 596, 597), through which reactive materials flow therethrough to one or more segment regions on a substrate. In some embodiments, a showerhead 590 consistent with the present disclosure may be configured such that as many as two substrate segment regions are exposed to reactive materials (e.g., gases) simultaneously.

For example, the showerhead 590 illustrated in FIG. 5 comprises a gas distribution segment port 595 having a plurality of gas openings 593 for delivering reactive gases to the surface of the substrate. Most notably, the configuration of the gas distribution segment port 595 may be used to improve the uniformity of the process on the substrate if required. Each gas opening 593 may have a diameter of approximately 0.014″, 0.018″, 0.024″ or any size suitable to deliver reactive gases to a substrate in a uniform manner. It should be understood by one having ordinary skill in the art that any number of gas distribution segment ports may be added to the showerhead 590 by adding additional body portions, depending upon the number of regions or segments one wants to or can define on a substrate.

In some embodiments, the shape of the gas distribution segment ports may resemble a sector. For instance, the sectors may be defined within a circularly-shaped showerhead 590 of 15, 30, or 60 degrees which may translate to a 15, 30, or 60 degree substrate segment region, respectively, of an underlying substrate.

For example, gas distribution segment port 595 has the shape and size of a sector of approximately 15 degrees. Notably, gas distribution segment port 596 has the shape and size of a sector of approximately 30 degrees and gas distribution segment port 597 has a shape and size of a sector of approximately 60 degrees.

Showerhead 590 also comprises a plurality of peripheral gas ports 599 which are disposed upon the perimeter of each gas distribution segment port of the showerhead assembly 590. In some embodiments, the plurality of peripheral gas ports 599 allows inert gases to flow therethrough to confine the reactive gases within a particular substrate segment region(s). As such, the peripheral gas ports may be utilized to form a purge gas curtain to isolate the precursor or reactant material within the exposed substrate segment region.

In some embodiments, showerhead 590 comprises two adjacent rows of peripheral gas ports 599 on two sides of each gas distribution segment port as shown in FIG. 5. Additionally, the flow rate of the inert gases dispensed from the plurality of peripheral gas ports 599 may be in the range from 100 to 2400 standard cubic centimeters per minute (sccm).

Showerhead 590 may also comprise a plurality of purge ports 598 through which inert gases may be used to purge reactive gases during an ALD process. One having ordinary skill in the art may appreciate that purge cycles may be implemented to remove excess reactive gases, such as precursors, after a deposition cycle.

Additionally, as shown in FIG. 5, the plurality of purge ports 598 are disposed in a central region of the showerhead 590 where a portion of the plurality of gas distribution segment ports are adjacent thereto. Accordingly, in some embodiments, a central region of the showerhead 590 allows purge gases to flow therethrough and may be not associated with a gas distribution segment port.

In addition, showerhead 590 includes at least one gas distribution segment port 597 which includes a slot 594 through which reactive materials (e.g., tested precursors and reactants) may flow uninhibited to a substrate (not shown) disposed below the showerhead 590 during processing.

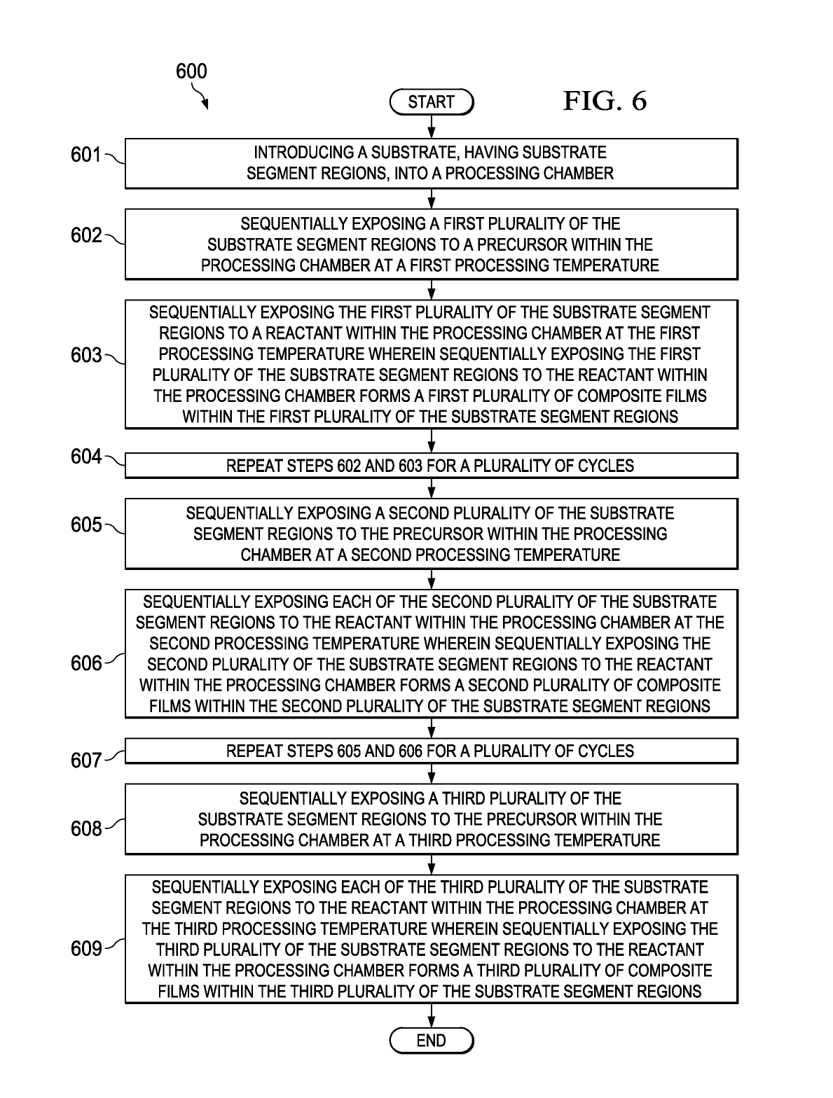

FIG. 6 is a flowchart 600 of a method for generating saturation curves using a segmented spatial atomic layer deposition (ALD) process. Block 601 provides introducing a substrate, having substrate segment regions, into a processing chamber. Next, block 602 includes sequentially exposing a first plurality of the substrate segment regions to a precursor within the processing chamber at a first processing temperature. In some embodiments, sequentially exposing the plurality of substrate segment regions to the precursor includes exposing each consecutive substrate segment region of the plurality of substrate segment regions in a clockwise direction.

In some embodiments, the first plurality of the substrate segment regions includes eight substrate segment regions which are sequentially exposed to the precursor. Exemplary precursors include Tris[dimethylamino]Silane (3DMAS), (3-Aminopropyl)triethoxysilane (APTES), tris(cyclopentadienyl)yttrium (3CpY), Trimethylaluminum (TMA), tetrakis-ethylmethylaminohafnium (TEMAHf), hafnium tetrachloride (HfCl₄), zirconium tetrachloride (ZrCl₄), and organometallic molecules.

Further, the first processing temperature may be any temperature to suitably form a film on a substrate consistent with an ALD process. In some embodiments, the first processing temperature is between 100° C. and 400° C. For instance, each substrate segment region of the first plurality of the substrate segment regions may be exposed to the first precursor in an ALD chamber at a process temperature of approximately 150° C.

Furthermore, the first plurality of the substrate segment regions are sequentially exposed to the precursor for a length of time consistent with forming a thin conformal film on a substrate via an ALD process. For example, the exposure time may be a time between 1 and 20 seconds. Most notably, each substrate segment region of the first plurality of substrate segment regions may be sequentially exposed to the first precursor for various exposure times. In some embodiments, the exposure time to the precursor may be chosen with regards to a successive exposure time to a reactant material. For instance, the eight substrate segment regions within the first plurality of the substrate segment regions may be sequentially exposed to the precursor for the time periods shown in Table 1 below.

TABLE 1

| Substrate | Substrate | Substrate | Substrate | Substrate | Substrate | Substrate | Substrate |
|---|---|---|---|---|---|---|---|
| Segment | Segment | Segment | Segment | Segment | Segment | Segment | Segment |
| Region 1 | Region 2 | Region 3 | Region 4 | Region 5 | Region 6 | Region 7 | Region 8 |
| 1 second | 2 seconds | 3 seconds | 5 seconds | 10 seconds | 10 seconds | 10 seconds | 10 seconds |

Table 1 provides that substrate segment regions 1-4 are sequentially exposed to the precursor at varying time durations (i.e., 1, 2, 3, 5 seconds) such that the substrate segment regions may be evaluated, at least in part, by the results of the varying time exposure to the precursor (as opposed to the reactant which each region is exposed to for a fixed time duration). Substrate segment regions 5-8 are sequentially exposed to the precursor for a fixed amount of time (e.g., 10 seconds) and the substrate segment regions may be evaluated, in part, by the results of a varying time exposure to a reactant.

In some embodiments of the present disclosure, a single substrate segment region may be exposed to a reactive material (precursor or reactant) in the ALD processing chamber for any amount of time. Referring back to FIG. 5, a gas distribution segment port may be used to expose a single substrate segment region to a reactive material for any time period.

Now referring to FIG. 4, the substrate support assembly 403 can rotate to set a desired substrate segment region directly under a particular gas distribution segment port. In some embodiments, the substrate support assembly 403 may be utilized to index the substrate from one substrate segment region to another in 1 second.

Next, block 603 provides sequentially exposing the first plurality of the substrate segment regions to a reactant within the processing chamber at the first processing temperature wherein sequentially exposing the first plurality of the substrate segment regions to the reactant within the processing chamber forms a plurality of composite films within the first plurality of the substrate segment regions. In some embodiments, sequentially exposing the plurality of substrate segment regions to the reactant includes exposing each consecutive substrate segment region of the plurality of substrate segment regions in a counterclockwise direction.

Exemplary reactants may include O₂ gas, plasma, H₂O, N₂, and H₂. For example, the exemplary reactants, when exposed to the first plurality of substrate segment regions, sequentially, may form a first composite film comprising any thin film such as TiN, Al₂O₃ and HfO₂.

In some embodiments, prior to sequentially exposing the first plurality of substrate segment regions to a reactant, the ALD processing chamber is purged of the precursor material. Purging may occur from 0 (or negligible time period)-120 seconds. For instance, the ALD processing chamber may be purged with an inert gas for 20 seconds to sufficiently clear the chamber of the precursor material while not significantly reducing the utilization of the ALD processing tool to perform other tasks (e.g., reactant dose).

In block 604, the steps in blocks 602, 603 are repeated a plurality of cycles. In particular, the steps are repeated enough times to achieve a desired thickness. For example, these steps may be repeated anywhere from 30 to 1000 cycles.

Next, block 605 provides sequentially exposing a second plurality of the substrate segment regions to the precursor within the processing chamber at a second processing temperature. In some embodiments, the second plurality of the substrate segment regions are sequentially exposed to the precursor in a similar manner as the technique(s) used to sequentially expose the first plurality of the substrate segment regions.

In some embodiments, each region of the second plurality of the substrate segment regions is sequentially exposed to the precursor in an ALD chamber with a second process temperature of approximately 150° C. Likewise, the eight substrate segment regions of the second plurality of the substrate segment regions may be sequentially exposed to the precursor for the time periods shown in Table 1.

Next, block 606 provides sequentially exposing each of the second plurality of the substrate segment regions to the reactant within the processing chamber at the second processing temperature wherein sequentially exposing the second plurality of the substrate segment regions to the reactant within the processing chamber forms a plurality of composite films within the second plurality of the substrate segment regions.

Further, in block 607, the steps in blocks 605, 606 are repeated a plurality of cycles. In particular, 605 and 606 are repeated enough times to achieve a desired thickness. For example, these steps may be repeated anywhere from 30 to 1000 cycles. In some embodiments, prior to sequentially exposing the second plurality of the substrate segment regions to the reactant, the ALD processing chamber is purged of the precursor material.

Next, block 608 provides sequentially exposing a third plurality of the substrate segment regions to the precursor within the processing chamber at a third processing temperature. In some embodiments, each region of the third plurality of substrate segment regions are sequentially exposed to the precursor in an ALD chamber with a third process temperature of approximately 200° C. Likewise, the eight substrate segment regions of the third plurality of the substrate segment regions may be sequentially exposed to the precursor for the time periods shown in Table 1.

Next, block 609 provides sequentially exposing each of the third plurality of the substrate segment regions to the reactant within the processing chamber at the third processing temperature wherein sequentially exposing the third plurality of the substrate segment regions to the reactant within the processing chamber forms a plurality of composite films within the third plurality of the substrate segment regions. In some embodiments, prior to sequentially exposing the third plurality of the substrate segment regions to the reactant, the ALD processing chamber is purged of the precursor material.

Accordingly, the method disclosed in flowchart 600 provides an efficient manner of testing the viability of precursor(s) and reactants(s), with various exposure times, varying temperatures, chamber pressures, reactive gas flow rates, etcetera.

Traditional methods of performing a plurality of experiments to evaluate reactive materials require a plurality of substrates. The present disclosure allows 24 experiments to be performed using a single substrate.

In some embodiments, testing the viability of a precursor or reactant may require about 24 experiments. Using a method consistent with the present disclosure, 24 experiments may be performed in approximately 19 hours. Additionally, for embodiments which two substrate segment regions are exposed to a new reactive material simultaneously, it has been determined that the time expended to complete 24 experiments is approximately 13 hours.

Multiple substrates may be used to further evaluate a new reactive material under additional processing conditions. As such, in the event that multiple substrates are used to evaluate a new reactive material, the time required for substrate transfer must be considered. In some embodiments, the substrate transfer time required to exchange out a processed substrate with a new substrate is approximately 1 minute.

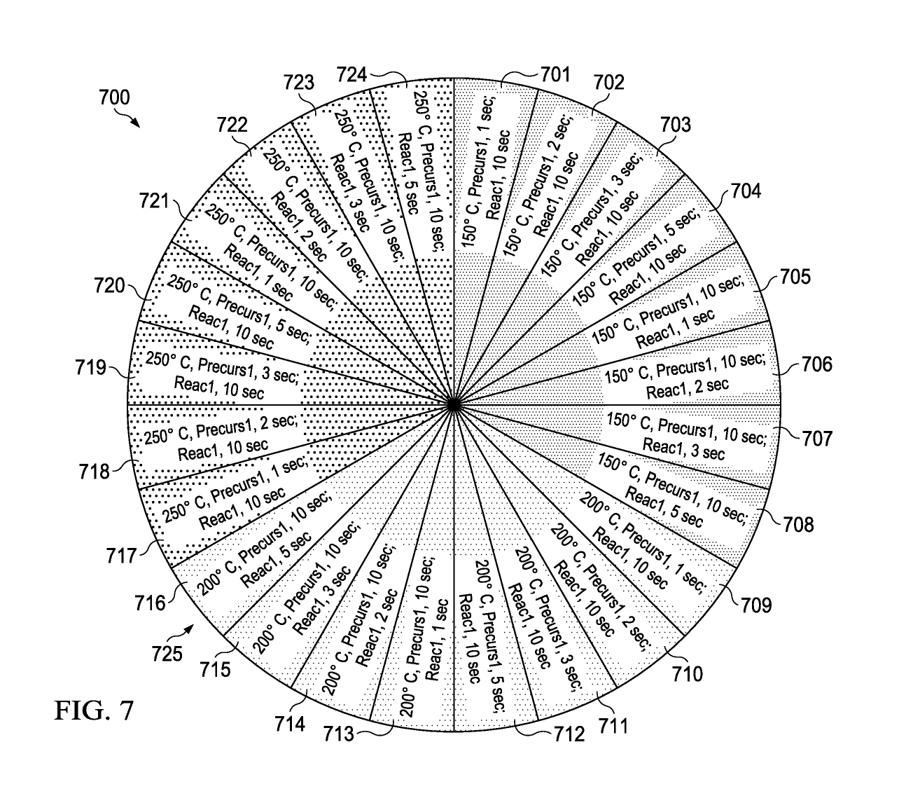

FIG. 7 is a schematic diagram illustrating the process conditions for performing 24 experiments to test the viability of a reactive material according to some embodiments of the present disclosure. In the figure, substrate 700 features three zones corresponding to substrate segment regions that are processed at the same process temperature. In the embodiment shown, Zone 1 includes substrate segment regions 701-708 which are to be processed at an exemplary processing temperature of 150° C.; Zone 2 includes substrate segment regions 709-716 which are to be processed at 200° C.; and finally Zone 3 includes substrate segment regions 717-724 which are to be processed at 250° C. Therefore, the evaluation of the precursor or reactant material may include the composite material's response to various process temperatures.

In addition, substrate segment regions 701-704, 709-712, and 717-720 may be exposed to a precursor at varying time durations such that the substrate segment regions may be evaluated, at least in part, by the results of the varying time exposure to the precursor (as opposed to a reactant which each region is exposed to for a fixed time duration). In contrast, substrate segment regions 705-708, 713-716, and 721-724 may be sequentially exposed to the precursor for a fixed amount of time (e.g., 10 seconds) such that the substrate segment regions may be evaluated, in part, by the results of a varying time exposure to a reactant.

It should be understood by one having ordinary skill in the art that the present disclosure is not limited to the dose times shown in FIG. 7 (1, 2, 4, 5, or 10 seconds). The dose times that the substrate segment regions 725 are sequentially exposed to may be between 1 and 20 seconds or any dose time consistent with an ALD process.

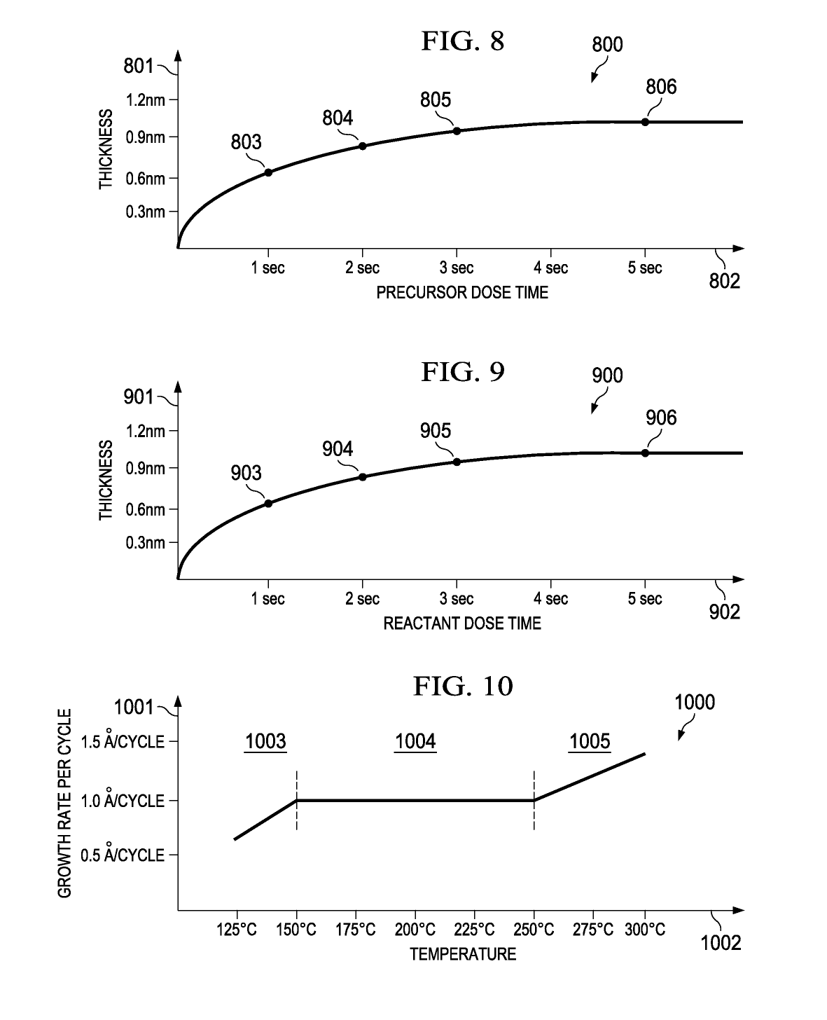

FIG. 8 illustrates a saturation curve 800. Saturation curve 800 shows the thicknesses (axis 801) measured of composite films formed by a method consistent with the present disclosure as a function of the precursor dose time (axis 802). Saturation curve 800 includes four points 803-806 disposed thereon and in some embodiments, points 803-806 represent four experiments. For example, points 803-806 may represent the precursor dose time and resulting thicknesses of the composite films on the substrate segment regions 701-704 illustrated in FIG. 7 at the Zone 1 temperature (150° C.).

Each substrate segment region may be characterized after the composite films are formed. The physical and electrical characteristics of the composite films formed in each substrate segment region may be compared such that a determination may be made to the viability of using the precursor or reactant or which process conditions yielded the most favorable results. For example, if a composite film of at least 1 nm is desired, the process conditions represented by point 806 may be deemed acceptable.

FIG. 9 illustrates another saturation curve 900. Saturation curve 900 illustrates the thickness (axis 901) measured of each composite film as a function of the reactant dose time (axis 902). Likewise, saturation curve 900 includes four points 903-906 disposed thereon which may also represent four experiments. For instance, points 903-906 may represent the reactant dose time and resulting thicknesses of the composite films within the substrate segment regions 705-708 illustrated in FIG. 7.

The thickness values shown in FIG. 8 and FIG. 9 may be an average value across the substrate for each respective precursor and reactant dose times, respectfully. For the embodiment shown in FIG. 7, the process conditions shown in the substrate segment regions 725 indicate that the substrate segment regions 725 were sequentially exposed to both the precursor and reactant for a specific dose time for three unique process temperatures.

For example, the process conditions for substrate segment regions 701, 709, 717 indicate that these substrate segment regions 725 were all sequentially exposed to the precursor for one second and to the reactant for 10 seconds but at different process temperatures (150° C., 200° C., 250° C.). Therefore, the thickness values indicated by points 803, 903 may be an average of the thickness measurements of the composite films in substrate segment regions 701, 709, and 717 and 705, 713, and 721, respectively.

FIG. 10 illustrates a graph 1000 displaying film growth rates for a span of process temperatures for an ALD process. In particular, graph 1000 displays a film growth rate per cycle (y-axis 1001) as a function of temperature (x-axis 1002) for an ALD process. As illustrated, graph 1000 contains three regions 1003-1005 which span across process temperatures for an ALD process. Region 1003 has a positive slope from 125° C. to 150° C. However, the growth rate per cycle is shown to be less than 1.0 Å/cycle. In some embodiments, the growth rate per cycle in region 1003 may be insufficient for ALD processing.

The growth rate per cycle in region 1004 (across temperatures 150° C.-250° C.) is approximately 1.0 Å/cycle. In some embodiments, the growth rate per cycle in region 1004 may be sufficient for ALD processing. In addition, region 1004 may have substantially the same growth rate per cycle across the span of temperatures within this region 1004.

Most notably, region 1004 may be referred to as an ALD window. One having ordinary skill in the art may appreciate that an ALD window may be characterized as a sustained growth rate per cycle over a span of temperatures. Accordingly, the ALD window may provide an indication of a suitable span of temperatures which yields a stable growth rate per cycle for an ALD process.

Further, region 1005 provides an indication of a growth rate per cycle which exceeds the growth rate associated with region 1004. The increase in growth rate within this region 1004 may be caused by thermal decomposition within the targeted vias, holes, etcetera. In some embodiments, process temperatures within this region 1004 are not suitable for ALD processing.

Methods relating to testing precursor and reactant materials for atomic layer deposition (ALD) processes have been described. It will be understood that the descriptions of some embodiments of the present disclosure do not limit the various alternative, modified and equivalent embodiments which may be included within the spirit and scope of the present disclosure as defined by the appended claims. Furthermore, in the detailed description above, numerous specific details are set forth to provide an understanding of various embodiments of the present disclosure. However, some embodiments of the present disclosure may be practiced without these specific details.

What is claimed is:

1. A method, comprising:
providing a substrate, wherein the substrate has a plurality of substrate segments defined thereon, and wherein the substrate is disposed upon a pedestal;
a) introducing the substrate into a processing chamber;
wherein the substrate is disposed upon a pedestal;
b) sequentially exposing the plurality of substrate segment regions to a precursor, wherein the substrate is held at a first processing temperature;
c) purging the precursor from the processing chamber;
d) sequentially exposing the plurality of substrate segment regions to a reactant, wherein the substrate is held at the first processing temperature;
e) purging the reactant from the processing chamber; and
f) repeating steps b)-e) for a plurality of cycles;
wherein each substrate segment region is sequentially exposed to the precursor for a unique processing time;
wherein the pedestal is rotated prior to exposing each next substrate segment region to the precursor and the reactant.

2. The method of claim 1, wherein the precursor is at least one of Tris[dimethylamino]Silane (3DMAS), (3-Aminopropyl)triethoxysilane (APTES), tris(cyclopentadienyl)yttrium (3CpY), Trimethylaluminum (TMA), tetrakis-ethylmethylaminohafnium (TEMAHf), hafnium tetrachloride (HfCl4), and zirconium tetrachloride (ZrCl4).

3. The method of claim 1, wherein sequentially exposing the plurality of substrate segment regions to the precursor includes exposing each consecutive substrate segment region of the plurality of substrate segment regions by rotating the pedestal in a clockwise direction and wherein sequentially exposing the plurality of substrate segment regions to the reactant includes exposing each consecutive substrate segment region of the plurality of substrate segment regions by rotating the pedestal in a counterclockwise direction.

4. The method of claim 1, wherein rotating the pedestal also rotates the substrate such that a next substrate segment region may be exposed to the precursor or the reactant.

5. A method, comprising:
a) introducing a substrate having a plurality of substrate segment regions defined thereon into a processing chamber;
b) sequentially exposing a first plurality of the substrate segment regions to a precursor within the processing chamber, wherein the substrate is held at the first processing temperature;
c) sequentially exposing the first plurality of substrate segment regions to a reactant, wherein the substrate is held at the first processing temperature;
d) repeating steps b) and c) for a plurality of cycles, thereby forming a first plurality of films;
e) sequentially exposing a second plurality of the substrate segment regions to the precursor within the processing chamber, wherein the substrate is held at a second processing temperature;
f) sequentially exposing the second plurality of substrate segment regions to a reactant, wherein the substrate is held at the second processing temperature;
g) repeating steps e) and f) for a plurality of cycles, thereby forming a second plurality of films;
h) sequentially exposing a third plurality of the substrate segment regions to the precursor within the processing chamber, wherein the substrate is held at a third processing temperature;
i) sequentially exposing the third plurality of substrate segment regions to a reactant, wherein the substrate is held at the third processing temperature; and
j) repeating steps h) and i) for a plurality of cycles, thereby forming a third plurality of films.

6. The method of claim 5 further comprising evaluating properties of each of the first, second, and third plurality of films, wherein evaluating comprises:
comparing a physical or electrical characteristic of each film.

7. The method of claim 5, wherein each of the first plurality, second plurality, and third plurality of the substrate segment regions includes eight substrate segment regions.

8. The method of claim 5, wherein the first processing temperature is 150° C., the second processing temperature is 200° C., and the third processing temperature is 250° C.

9. The method of claim 5 further comprising purging the precursor from the processing chamber after exposing a plurality of the substrate segment regions to the precursor and prior to sequentially exposing a plurality of the substrate segment regions to the reactant and purging the reactant from the processing chamber after exposing a plurality of the substrate segment regions to the reactant and prior to sequentially exposing a next plurality of segment regions to the precursor.

10. The method of claim 9, wherein purging the first precursor from the processing chamber occurs in a time ranging from 0 to 120 seconds.

11. The method of claim 5, wherein sequentially exposing each plurality of substrate segment regions to the precursor includes exposing consecutive substrate segment regions of each plurality of the substrate segment regions by rotating the pedestal in a clockwise direction and wherein sequentially exposing each plurality of the substrate segment regions to the reactant includes exposing consecutive substrate segment regions of the plurality of substrate segment regions by rotating the pedestal in a counterclockwise direction.

12. The method of claim 5, wherein the processing chamber is an ALD processing chamber.

13. The method of claim 5 further comprising forming a purge gas curtain at a perimeter of a substrate segment region to isolate the precursor or the reactant to the exposed substrate segment region.

14. The method of claim 5, wherein steps b)-c), e)-f), and h)-i) are repeated for a plurality of a cycles in a range from 30 to 1000 cycles.

15. The method of claim 5, wherein the first processing temperature is 250° C., the second processing temperature is 350° C., and the third processing temperature is 400° C.

16. The method of claim 5, wherein two of the substrate segment regions are exposed to the first precursor simultaneously.

17. The method of claim 5, wherein each of the substrate segment regions are approximately 15 degree sectors of a circularly-shaped substrate.
